(19) United States
(12) Patent Application Publication
(10) Pub. No.: US 2002/0197885 A1
(43) Pub. Date: Dec. 26, 2002

(54) Method of making a semiconductor transistor by implanting ions into a gate dielectric layer thereof

(76) Inventors: Jack Hwang, Portland, OR (US); Mitchell C. Taylor, Lake Oswego, OR (US)

Correspondence Address: Stephen M. De Klerk, Blakely, Sokoloff, Taylor & Zafman LLP, Seventh Floor, 12400 Wilshire Boulevard, Los Angeles, CA, 90025-1026, US

(21) Appl. No.: 09/887,910

(22) Filed: Jun. 22, 2001

(51) Int. Cl. H01L 21/31; H01L 21/469

(52) U.S. Cl. 438/778; 438/783; 438/784; 438/788

(57) ABSTRACT

A method described for making a semiconductor transistor having a thin gate dielectric layer with a high k-value but without any impurities in a channel in silicon directly below the gate dielectric layer. An apparatus is used which pulses a cathode to create a plasma generating voltage potential between the cathode and an anode provided by a wall of a chamber of the apparatus. The plasma generating voltage generates an ion plasma out of a gas in the chamber. The ion plasma is maintained transient which allows for better control of its energy. A portion of a wafer stand is pulsed with a small voltage which extracts and accelerates ions out of the plasma into a silicon dioxide gate dielectric layer formed on a wafer in the chamber.

### BACKGROUND OF THE INVENTION

1). Field of the Invention

This invention relates to a method of making a semiconductor transistor, and in particular to a method in which a gate dielectric layer of the transistor is made by implanting ions.

2). Discussion of Related Art

Integrated circuit chips are formed by manufacturing a multitude of semiconductor devices, particularly transistors, on a semiconductor substrate, and then interconnecting the devices with upper level metal lines.

A transistor is made by forming a gate dielectric layer on the semiconductor material, followed by a conductive gate, typically from polysilicon, on the gate dielectric layer. Source and drain regions are formed in the semiconductor material on the opposing sides of the conductive gate. Only when a voltage is applied to the conductive gate, does current flow from the source region to the drain region.

To ensure quick activation or “switching” of the current, it is generally required that the gate dielectric layer be very thin and be made of a material having a high k-value. Silicon of the substrate is usually exposed to oxygen which oxidizes the silicon to create silicon dioxide. Silicon dioxide however has a relatively low k-value of about 3.9.

Silicon nitride by contrast has a relatively high k-value of about 7.5 and is thus more desirable. One process that may be used for forming a silicon nitride layer is a conventional plasma process. A silicon wafer having a silicon dioxide gate dielectric layer formed thereon is inserted into a chamber, a nitrogen gas is introduced into the chamber, and an alternating voltage between an anode and a cathode is switched on. The voltage remains on for a long period of time, resulting in generation of a steady-state plasma. The ion energy of a steady-state plasma cannot be easily varied, resulting in the inability to optimize the process.

FIG. 1 illustrates implantation depth of nitrogen ions utilizing a conventional plasma technique. A silicon dioxide layer 100 having a thickness of approximately 20 Å is formed on a silicon substrate 102. Nitrogen ions are implanted into the silicon dioxide layer 100 and also into the silicon 102 directly below the silicon dioxide layer 100. The nitrogen in the silicon 102 below the silicon dioxide layer 100 contaminates the silicon 102 resulting in a smaller current that flows through the silicon 102. Too shallow of a nitridation can cause undesirable interfacial interactions and less optimal average dielectric constant.

### BRIEF DESCRIPTION OF THE DRAWINGS

The invention is described by way of example with reference to the accompanying drawings wherein:

FIG. 1 is a graph illustrating ion implantation into a gate dielectric layer utilizing a conventional plasma technique;

FIG. 2 is a cross-sectional side view of apparatus used for ion implantation into a gate dielectric layer, according to an example of the invention;

FIG. 3 is a graph illustrating a voltage on a cylindrical cathode of the apparatus;

FIG. 4 is a graph illustrating a voltage on a portion of a stand of the apparatus on which a wafer is located;

FIG. 5 is a graph illustrating ion plasma concentration due to the voltage in FIG. 3;

FIG. 6 is a graph illustrating implantation depth of ions utilizing the apparatus us FIG. 2;

FIG. 7 is a cross-sectional side view of a transistor which is manufactured with the gate dielectric layer forming part of the transistor; and

FIG. 8 is a graph illustrating selection of implantation voltages for different gate dielectric layers.

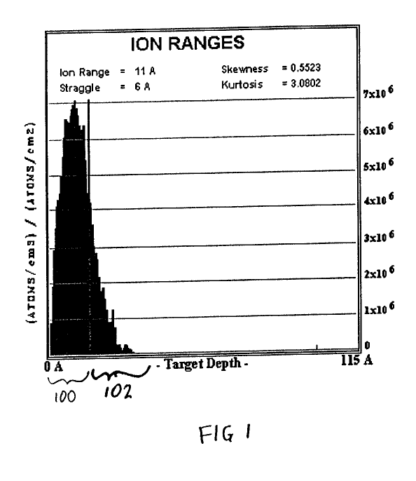

### DETAILED DESCRIPTION OF THE INVENTION

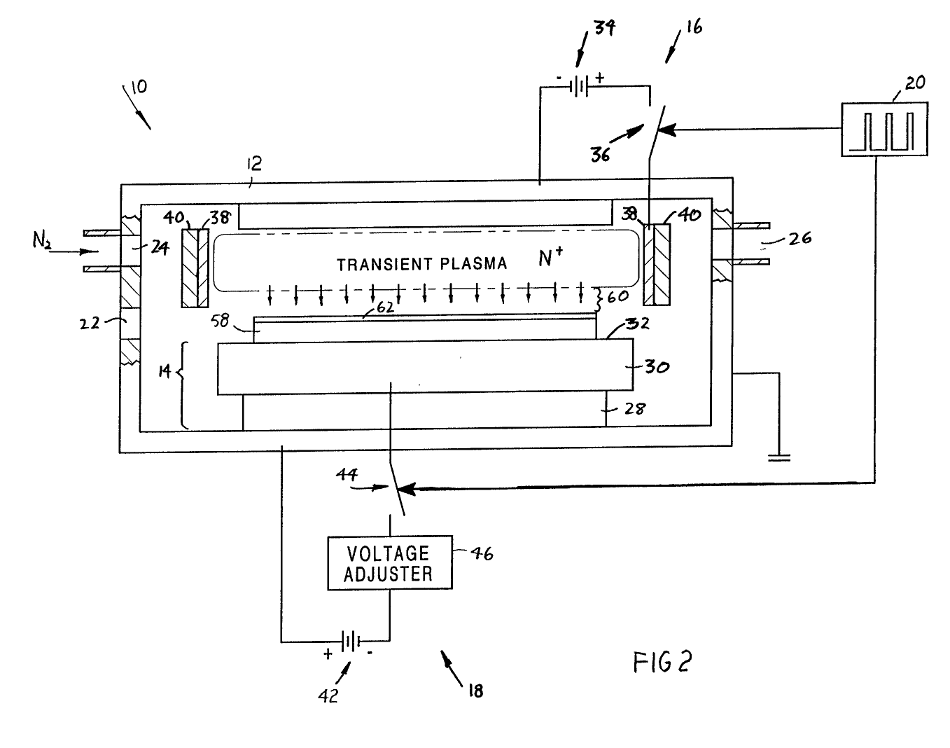

FIG. 2 of the accompanying drawings illustrates apparatus 10 which may be used for carrying out the method according to the invention. The apparatus 10 includes a wafer processing chamber 12, a wafer stand 14, plasma generating apparatus 16, ion implanting apparatus 18, and switching apparatus 20.

The chamber 12 has a slit 22, an inlet port 24, and an outlet port 26. The slit 22 is large enough to allow for a blade carrying a substrate to be inserted therethrough. The inlet and outlet ports 24 and 26 are on opposing sides of the chamber 12. A source of nitrogen gas is connected to the inlet port 24. The chamber 12 is made of an electrically conductive metal which serves as an anode of the plasma generating apparatus 16 and a cathode for the ion implanting apparatus 18. The chamber 12 is connected to ground and is thus maintained at 0 V.

The stand 14 includes a lower portion 28 and an upper portion 30. The lower portion 28 is made of an electrically insulative material. The upper portion 30 is made of a conductive material and is located on the lower portion 28. The upper portion 30 is electrically insulated from the chamber 12 by the lower portion 28. A different voltage can thus be applied to the upper portion 30 than to the chamber 12. The upper portion 30 has a horizontal upper surface 32 on which a substrate can be located.

The plasma generating apparatus 16 includes a plasma voltage supply 34, a plasma switch 36, a cylindrical cathode 38, and a cylindrical anti-spark ring 40.

The cylindrical cathode 38 is made of a conductive metal and is surrounded by the cylindrical anti-spark ring 40 which is made of a nonconductive material. Should a voltage be applied to the cylindrical cathode 38, the cylindrical anti-spark ring 40 will prevent sparking which would cause a short between the cylindrical cathode 38 and the chamber 12.

The plasma voltage supply 34 has positive and negative terminals. The positive terminal is maintained at a constant voltage of 5 kV relative to the negative terminal. The negative terminal of the plasma voltage supply 34 is connected to the chamber 12. Because the chamber 12 is grounded, the negative terminal of the plasma voltage supply 34 is at 0 V. The positive terminal of the plasma voltage supply 34 is connected through the plasma switch 36 to the cylindrical cathode 38. The cylindrical cathode 38 is at the voltage of the positive terminal of the plasma voltage supply 34, and is at 0 V when the plasma switch 36 is open. When the plasma switch 36 is closed, the cylindrical cathode 38 is thus at 5 kV and the cylindrical cathode 38 is at 0V when the plasma switch 36 is open. A voltage potential of 5 kV exists between the cylindrical cathode 38 and the chamber 12 when the plasma switch 36 is closed, the chamber 12 acting as an anode.

The ion implanting apparatus 18 includes an implanting voltage supply 42, and implanting switch 44, and a voltage adjuster 46.

The implanting voltage supply 42 has a positive and negative terminal with the negative terminal maintained at a constant (direct-current) voltage of about 500 V below (−500 V) the positive terminal. The positive terminal is connected to the chamber 12 and is thus at 0 V. The negative terminal of the implanting voltage supply 42 is connected in series through the voltage adjuster 46 and the implanting switch 44 to the upper portion 30 of the stand 14. A line is drawn from the switch 44 to the upper portion 30 but it should be understood that the switch 44 is not connected to the chamber 12.

The voltage adjuster 46 has an input terminal which is directly connected to the negative terminal of the implanting voltage supply 42. The input terminal of the voltage adjuster 46 is thus at −500 V. The voltage adjuster 46 maintains the voltage at the output terminal at a fraction of the voltage of the input terminal. A voltage regulator may for example be provided to adjust the voltage from the voltage at the input terminal to that of the voltage at the output terminal. In addition, the voltage adjuster 46 may be manually adjusted so that the voltage at the output terminal can be adjusted up or down. The voltage at the output terminal, for purposes of the invention, may be adjusted to between −10 V and −80 V. The output terminal of the voltage adjuster 46 is connected through the implanting switch 44 to the upper portion 30 of the stand 14. When the implanting switch 44 is closed, the upper portion 30 is at the voltage of the output terminal of the voltage adjuster 46. When the implanting switch 44 is open, the voltage of the upper portion 30 is 0 V.

The switching apparatus 20 switches the plasma switch 36 and the implanting switch 44. For practical purposes, the plasma switch 36 and the implanting switch 44 are switched on together and switched off together. The switching apparatus 20 can be adjusted so that the length of time during which the switches 36 and 44 are closed is adjusted, and the period of time during which the switches 36 and 44 are open is adjusted.

FIG. 3 illustrates how the plasma switch 36 is switched. The plasma switch 36 is switched on for a period 50, followed by a period 52 during which the plasma switch 36 is switched off. The period 50 is about 1% of the period 52 and is generally less than 1 second, typically a few milliseconds. The periods 50 and 52 when repeated in a periodic manner so as to create a square pulsing voltage on the cylindrical cathode 38 with a maximum voltage of 5 kV, being on for the periods 50, and being off for the intervening periods 52.

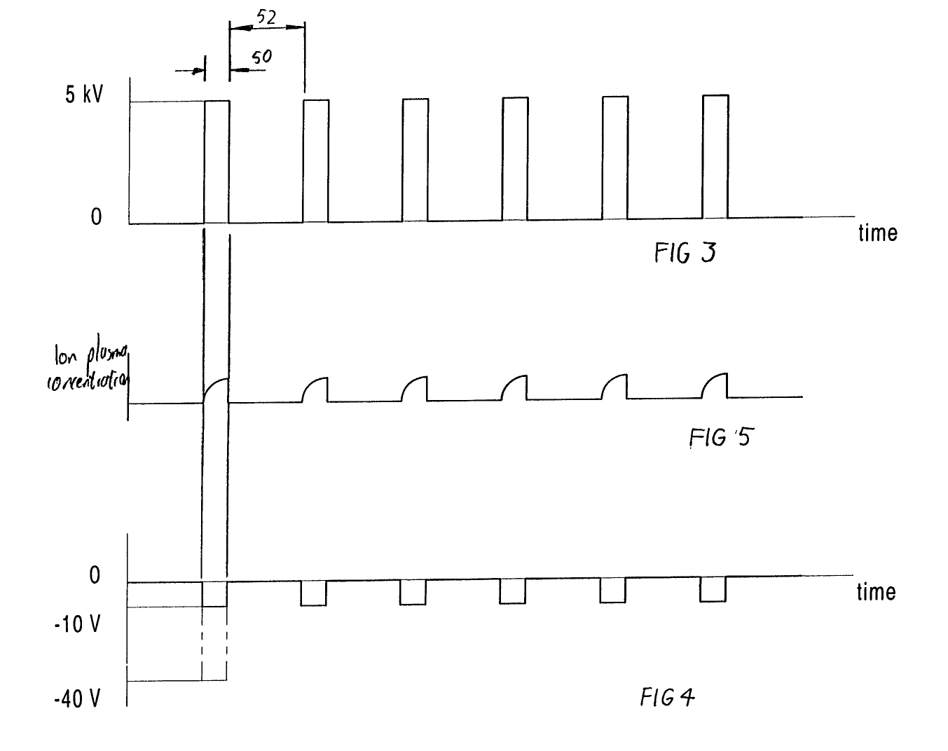

FIG. 4 illustrates how the voltage on the upper portion 30 is alternated. In FIG. 4, the voltage adjuster 46 is adjusted so that the upper portion 30 is at a voltage of −10 V when the implanting switch 44 is closed. As can be seen from FIG. 3 and FIG. 4 that the upper portion 30 is at −10 V when the cylindrical cathode 38 is a 5 kV and that the voltage on the upper portion 30 is at 0 V when the cylindrical cathode 38 is at 0 V. In the example given, the maximum magnitude of voltage on the cylindrical cathode 38 is 500 times the maximum magnitude of the voltage on the upper portion 30 but the voltage on the upper portion 30 has an opposite sign than the voltage on the cylindrical cathode 38.

In use, a wafer substrate 58 is inserted through the slit 22 into the chamber 12 and located on the upper surface 32 of the upper portion 30. The wafer substrate 58 is at substantially the same voltage as the upper portion 30.

Nitrogen gas is introduced through the inlet port 24 into the chamber and flows into the cylindrical cathode 38. A constant flow of nitrogen gas flows into the inlet port 24 and out of the outlet port 26.

When a voltage is created on the cylindrical cathode 38, a voltage difference between the cylindrical cathode 38 and the chamber 12 increases discussed with reference to FIG. 3. The increase in the voltage difference generates a transient ion plasma out of some of the nitrogen gas. The ion plasma consists of nitrogen ions having positive charge. The plasma is located within the cylindrical cathode 38 above the substrate 58. An upper edge of the plasma is located near an upper wall of the chamber 12. A lower edge of the plasma is located distant from an upper surface of the wafer substrate 58 so that a gap 60 exists in the lower edge of the plasma and an upper surface of the wafer substrate. The gap 60 is a few millimeters wide.

The wafer substrate 58 is made of a doped semiconductor material such as P-doped silicon. A thin gate dielectric layer 62 is formed on the wafer substrate 58 prior to its insertion into the chamber 12. The gate dielectric layer 62 forms part of a transistor which is subsequently manufactured in and on the wafer substrate 58. For optimal performance of the transistor, it is required that the gate dielectric layer 62 be very thin and be made of a material with a high k-value. The gate dielectric layer 62, when inserted into the chamber 12, is typically made of silicon dioxide having a thickness of approximately 20 Å. The silicon dioxide gate dielectric layer 62 is formed by exposing the silicon wafer substrate 58 to oxygen in water.

A disadvantage of a silicon dioxide gate dielectric layer is that it has a relatively low k-value of about 3.9. A silicon nitride gate dielectric layer by contrast has a relatively high k-value of about 7.5, which is more desirable. The k-value of a silicon dioxide gate dielectric layer can be increased by implanting nitrogen molecules into the silicon dioxide gate dielectric layer.

Referring to FIG. 5, an ion plasma concentration increases when a voltage is applied to the circular cathode 38. The voltage on the cathode 38 is switched off before the plasma can reach a steady-state condition. The plasma, when existing is thus in a transient condition at all times. By maintaining the plasma in a transient state the ion energy can be controlled with the lower electrode.

By pulsing the voltage on the upper portion 30 as described with reference to FIG. 4, a voltage differential of −10 V is created between the upper portion 30 and the plasma. The voltage potential only exists when the implanting switch 44 is closed. Ions of the plasma are accelerated from the plasma towards the silicon dioxide gate dielectric layer 62 when the implanting switch 44 is closed. When the implanting switch 44 is open, the ions are not accelerated towards the gate dielectric layer 62.

The combined effect of the creation of the confined transient plasma utilizing the plasma generating apparatus 16 and creating a pulsed voltage on the upper portion 30, results in tight control in the amount and the energy of ions being implanted into the gate dielectric layer 62. The energy of the ions being implanted can be sharply defined and controlled for the optimum profile.

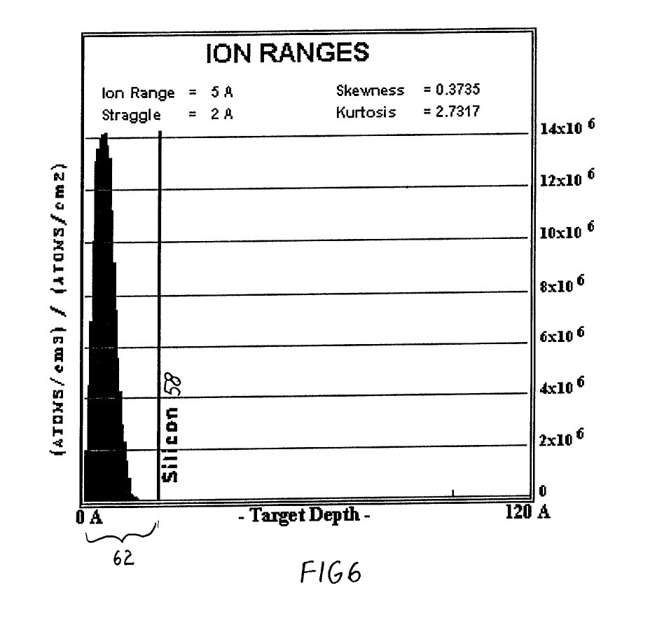

FIG. 6 illustrates the concentration and depth of ions being implanted into the gate dielectric layer 62 and the silicon wafer substrate 58. It can be seen that all the ions are implanted into the gate dielectric layer 62 only. No ions are implanted into the silicon wafer substrate 58, even though the gate dielectric layer 62 is only approximately 20 Å thick. A result of the implantation is that a k-value of the gate dielectric layer 62 is increased while the composition of the silicon of the wafer substrate 58 directly below the silicon dioxide layer 62 remains unchanged. The implant should not be so shallow as to reside only on the surface as it would create potentially unwanted interface effects. To get the maximum increase in k-value of the dielectric material, the implant should penetrate as deeply as possible without going beyond the interface with the silicon below.

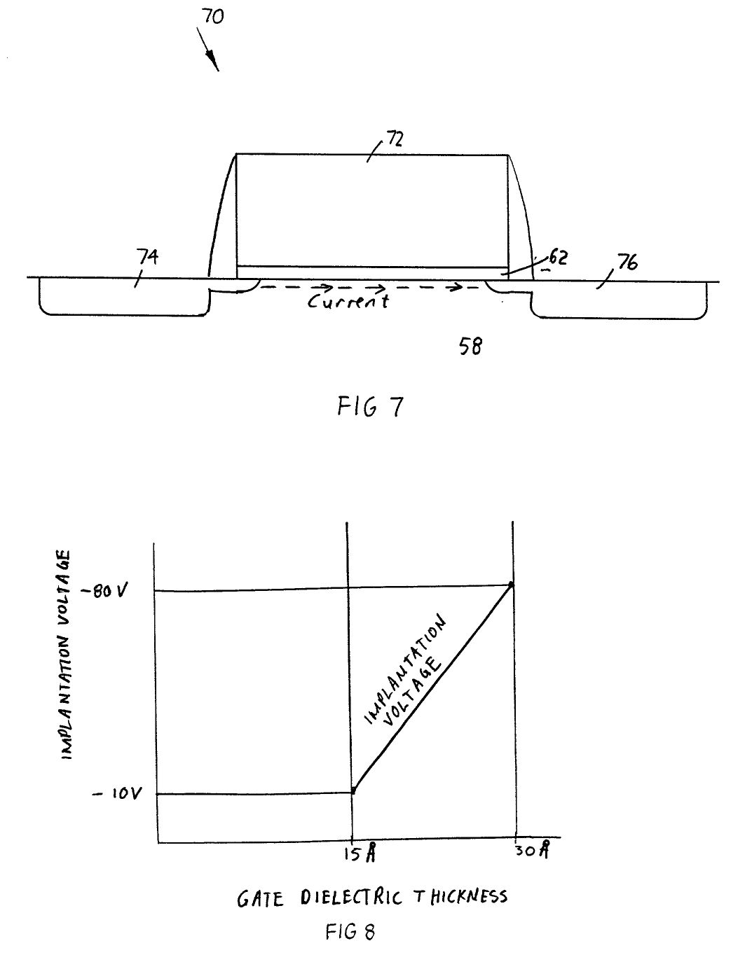

The wafer substrate 58 is subsequently removed from the chamber 12 and a multitude of semiconductor devices, including transistors, are formed thereon. FIG. 7 illustrates one transistor 70 which is so manufactured. A conductive gate 72 is formed directly on the gate dielectric layer 62. N-doped source and drain regions 74 and 76 are formed on opposing sides of the gate 72. Subsequent metalization and dielectric layers are formed above the transistor 72. A supply voltage can be provided through one metal line to the source 74 and a drain voltage can be connected to a metal line connected to the drain 76. When a voltage is applied to the gate 72, current flows from the source 74 to the drain 76. The current from the source 74 to the drain 76 is thus switched by applying a voltage to the gate 72. A switch speed of the current is increased because the gate dielectric layer 62 is relatively thin and its k-value is relatively high. The current from the source 74 to the drain 76 is however not affected by any impurities.

FIG. 8 illustrates how implantation voltage is selected for different gate dielectric layers. The magnitude of the selected implantation voltage is increased for an increase in thickness of the gate dielectric layer. The implantation voltage is adjusted to about −10V (maximum magnitude) for a 15 Å gate dielectric layer and to about −80V (maximum magnitude) for a 30 Å gate dielectric layer. The range of from −10-V to −80V is however still relatively low when compared to conventional voltages used for implantation of ions to create for example source and drain regions of transistors.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A method of making a semiconductor transistor, comprising:
locating a substrate of a doped semiconductor material in a chamber;
introducing a gas into the chamber;
repeatedly increasing and decreasing a plasma generating voltage potential across the gas in the chamber between a cathode and an anode while the substrate is in the chamber, a transient ion plasma generating from the gas after an increase in magnitude of the plasma generating voltage potential and degenerating after a decrease in magnitude of the plasma generating voltage potential;
repeatedly increasing and decreasing an implantation voltage potential between the ion plasma and the substrate, ions of the plasma accelerating towards and implanting into a gate dielectric layer formed on the substrate after an increase in magnitude of the implantation voltage potential; and
forming a conductive transistor gate on the dielectric layer implanted with the ions.

2. The method of claim 1 wherein the gas includes nitrogen.

3. The method of claim 2 wherein the ions include nitrogen ions.

4. The method of claim 1 wherein the plasma generating voltage is generated by repeatedly increasing a voltage of the cathode to a positive voltage and decreasing the voltage of the cathode.

5. The method of claim 1 wherein the plasma generating voltage has a magnitude of at least 1 kV.

6. The method of claim 1 wherein subsequent increases in the plasma generating voltage are spaced by less than 1 second.

7. The method of claim 1 wherein the plasma generating voltage is less than 50% of its maximum for at least 95% of the time.

8. The method of claim 1 wherein the ion plasma generates in an area in the chamber between the anode and the substrate.

9. The method of claim 1 wherein the implantation voltage potential has a maximum voltage potential that has a maximum magnitude of less than 80 V.

10. The method of claim 9 wherein the implantation voltage potential has a maximum magnitude of more than 10V.

11. The method of claim 1 wherein the implantation voltage potential has a magnitude of less than 4% of a maximum magnitude of the plasma generating voltage.

12. The method of claim 1 wherein a period of the implantation voltage potential is substantially the same as a period of the plasma generating voltage potential.

13. The method of claim 1 wherein the plasma generating voltage potential is generated by applying a voltage having a positive maximum to the cathode and the implantation voltage potential is created by applying a voltage having a negative maximum to the substrate.

14. The method of claim 1 wherein the ions increase a dielectric constant of the gate dielectric layer.

15. The method of claim 1 further comprising:
adjusting a magnitude of the implantation voltage potential.

16. A method of making a semiconductor transistor, comprising:
locating a substrate of a doped semiconductor material in a chamber;
introducing a gas into the chamber;
repeatedly increasing a voltage on a cathode to a positive value and decreasing the voltage on the cathode so as to repeatedly increase and decrease a plasma generating voltage potential across the gas in the chamber between the cathode and an anode while the substrate is in the chamber, an ion plasma generating from the gas after an increase in magnitude of the plasma generating voltage potential and degenerating after a decrease in magnitude of the plasma generating voltage potential;
repeatedly decreasing a voltage on the substrate to a negative value and increasing the voltage on the substrate so as to repeatedly decrease and increase an implantation voltage potential between the ion plasma and the substrate, ions of the plasma accelerating towards and implanting into a gate dielectric layer formed on the substrate after a decrease of the implantation voltage potential; and
forming a conductive transistor gate on the dielectric layer implanted with the ions.

17. The method of claim 16 wherein the implantation voltage potential has a maximum magnitude of more than 10V but less than 20V.

18. The method of claim 16 wherein a period of the implantation voltage potential is substantially the same as a period of the plasma generating voltage potential.

19. The method of claim 16 wherein the ions increase a dielectric constant of the gate dielectric layer.

20. A method of making a semiconductor transistor, comprising:
locating a substrate of a doped semiconductor material in a chamber;
introducing a gas into the chamber;
repeatedly
(i) (a) increasing a plasma generating voltage potential across the gas in the chamber between a cathode and an anode while the substrate is in the chamber, a transient ion plasma generating from the gas after an increase in magnitude of the plasma generating voltage potential, and (b) decreasing an implantation voltage potential between the ion plasma and the substrate, the ions accelerating towards and implanting into a gate dielectric layer formed on the substrate after an increase in magnitude of the implantation voltage potential and
(ii) (a) decreasing the plasma generating voltage potential, the plasma degenerating after a decrease in magnitude of the plasma generating voltage potential, and (b) increasing the implantation voltage potential, whereafter fewer ions implant into the gate dielectric layer; and
forming a conductive transistor gate on the dielectric layer implanted with the ions.

21. The method of claim 20 wherein subsequent increases in the plasma generating voltage are spaced by less than 1 second.

22. The method of claim 20 wherein the plasma generating voltage is less than 50% of its maximum for at least 95% of the time.
